(19) United States
(12) Patent Application Publication
(10) Pub. No.: US 2017/0110330 A1
(43) Pub. Date: Apr. 20, 2017

(54) SYSTEM AND METHOD FOR LITHOGRAPHIC SURFACE TEXTURING

(71) Applicant: ARIZONA BOARD OF REGENTS ON BEHALF OF ARIZONA STATE UNIVERSITY, Scottsdale, AZ (US)

(72) Inventors: Jeayoung Choi, Chandler, AZ (US); Christiana Honsberg, Tempe, AZ (US)

(21) Appl. No.: 15/126,214

(22) PCT Filed: Mar. 11, 2015
(86) PCT No.: PCT/US2015/019939

§ 371 Date: Sep. 14, 2016

Related U.S. Application Data
(60) Provisional application No. 61/953,228, filed on Mar. 14, 2014.

(51) Int. Cl. H01L 21/308; H01L 21/3065; H01L 21/306

(52) U.S. Cl. CPC H01L 21/3088; H01L 21/3085; H01L 21/3086; H01L 21/3081; H01L 21/30604; H01L 21/3065; H01L 31/02363

(57) ABSTRACT

A method is provided for manufacturing an etched surface. The method includes the steps of assembling a plurality of particles on the surface of a substrate and etching the plurality of particles to vary the size and spacing of the particles on the surface of the substrate. The method further includes depositing a mask material on the substrate including the etched particles, removing the etched particles from the substrate, thereby exposing the substrate beneath the plurality of particles, and selectively etching the substrate exposed after removal of the plurality of particles.

### CROSS-REFERENCE TO RELATED APPLICATIONS

This application is based on, claims the benefit of, and incorporated herein by reference, U.S. Provisional Patent Application No. 61/953,228 filed on Mar. 14, 2014 and entitled, “System and Method for Lithographic Surface Texturing.”

### STATEMENT REGARDING FEDERALLY SPONSORED RESEARCH

This invention was made with government support under 1041895 awarded by National Science Foundation. The government has certain rights in the invention.

### FIELD OF THE DISCLOSURE

This disclosure relates to pattern-based lithography, and more particularly to a system and a method for scalable self-assembled patterns for lithographic surface texturing.

### BACKGROUND OF THE INVENTION

Surface texturing is an important technique in the field of small-scale fabrication. This technique may be used to alter the topography of a surface in order to improve the light management characteristics of the surface. For example, surface texturing may provide a significant reduction in light reflection, increased incident light absorption via increased optical path length (diffraction), and improved internal reflection to reduce the fraction of light that escapes from an incident surface. Applications of surface texturing span a variety of industries, including renewable energy, telecommunications, information processing, illumination, spectroscopy, holography, medicine, military technology, agriculture, and robotics.

For certain applications, such as the fabrication of solar panels, one or more lithography techniques may be used to apply surface texturing across a large surface area. However, conventional lithography techniques like electron beam lithography, photolithography, and/or laser interference lithography may not be appropriate techniques for the preparation of large surface areas. With respect to industrial solar cell fabrication processes, these conventional techniques may be relatively time-consuming and expensive processes. Thus, there is a need for a more cost-effective and time efficient texturing method for use over relatively large surface areas.

One cost effective and efficient approach to mask large surface areas for lithography relies upon the self assembly of colloidal particles to form a lithography mask. Self-assembly of colloidal particles on a surface has been applied to the fabrication of optical devices, biochips, biosensors, and so forth. Due to the wide range of applications, many techniques have been developed to produce uniform colloidal particle assemblies with large area coverage, including Langmuir-Blodgett deposition, convective self-assembly, and dip-coating. Although some efforts have been made toward improving colloidal particle assembly protocols, it may be necessary to develop a separate, optimized protocol for each different size and shape of particle used. More generally, once applied to a surface, the dimensions of a lithography mask may not be altered to adjust the size or spacing of the features of the mask.

### SUMMARY OF THE INVENTION

The present disclosure overcomes the aforementioned drawbacks by providing a system and method for lithographic surface texturing.

According to one embodiment, a method of manufacturing an etched surface includes assembling a primary mask material including a plurality of particles on the surface of a substrate, etching the first mask material, depositing a secondary mask material on the substrate including the etched primary mask material, removing at least a portion of the etched primary mask material from the substrate, thereby exposing the substrate beneath the primary mask material, and etching the newly exposed substrate.

In one aspect, the method further includes treating the primary mask material prior to the step of depositing the secondary mask material to remove organic contaminants.

In another aspect, treating the primary mask material to remove organic contaminants includes an ultraviolet-ozone treatment.

In yet another aspect, the plurality of particles includes silica spheres.

In still another aspect, the plurality of particles has an average diameter of about 10 nanometers to about 10 micrometers.

In a further aspect, the step of assembling the particles further includes forming a self-assembled monolayer.

In one aspect, the step of etching the first mask material further includes reactive ion etching.

In another aspect, the step of etching the first mask material further includes varying at least one of a size and an interparticle spacing of the plurality of particles.

In yet another aspect, the secondary mask material includes a metal.

In another aspect, the metal includes at least one of chromium and nickel.

In still another aspect, the step of removing at least a portion of the etched primary mask material further includes at least one of hydrofluoric acid etching and buffered oxide etching.

In a further aspect, the step of etching the newly exposed substrate further includes at least one of reactive ion etching and wet etching.

In another embodiment, a method of manufacturing an etched surface includes spin-coating a primary mask material onto a target surface of a substrate, the primary mask material comprising a plurality of spherical particles, the particles self-assembling into an ordered monolayer on the target surface, etching the particles using a reactive ion composition, decontaminating the particles and the target surface with an ultraviolet ozone treatment, depositing a secondary mask material on the particles and a portion of the target surface not masked by the particles, removing at least a portion of the particles from the substrate, thereby exposing a remaining portion of the target surface previously masked by the particles, and etching the newly exposed substrate.

In one aspect, the particles are silica spheres.

In another aspect, the silica spheres have an average diameter of about 10 nanometers to about 10 micrometers.

In yet another aspect, the silica spheres have an average diameter of about 100 nanometers to about 5 micrometers.

In still another aspect, the silica spheres have an average diameter of about 500 nanometers to about 1500 nanometers.

In a further aspect, the step of etching the particles further includes varying at least one of a size and an interparticle spacing of the particles.

In one aspect, the secondary mask material includes a metal.

In another aspect, the metal includes at least one of chromium and nickel.

In yet another aspect, the step of removing at least a portion of the particles from the substrate further includes at least one of hydrofluoric acid etching and buffered oxide etching.

In still another aspect, the step of etching the newly exposed substrate further includes at least one of reactive ion etching and wet etching.

In a further aspect, the particles self assemble into a hexagonal close packed arrangement.

In one aspect, the step of etching the particles further includes increasing an interparticle distance between the particles.

In another aspect, the step of etching the particles further includes one of anisotropic etching and isotropic etching.

The foregoing and other aspects and advantages of the invention will appear from the following description. In the description, reference is made to the accompanying drawings which form a part hereof, and in which there is shown by way of illustration an example embodiment of the invention. Such embodiment does not necessarily represent the full scope of the invention, however, and reference is made therefore to the claims and herein for interpreting the scope of the invention.

### BRIEF DESCRIPTION OF THE DRAWINGS

FIG. 1 is an SEM image of an example substrate including an as-deposited self-assembled monolayer of 1.57 μm silica spheres on the surface of a silicon wafer as viewed from above at 20,000× magnification. The scale bar represents 1 μm.

FIG. 1A is a schematic illustration showing a plan view of an example substrate patterned with a plurality of spherical particles.

FIG. 1B is an enlarged partial view of the example substrate as taken along the line 1B of FIG. 1A showing the particles in an ordered, uniform, hexagonal close packed arrangement similar to FIG. 1.

FIG. 1C is a partial elevational view of the example substrate as taken along the line 1C-1C of FIG. 1B.

FIG. 2 is an SEM image of the substrate of FIG. 1 after pattern etching to reduce the size of the silica spheres. The scale bar represents 1 μm.

FIG. 2A is an enlarged partial view similar to FIG. 1B showing the example substrate after exposing the particles to etching similar to FIG. 2.

FIG. 3 is an SEM image of the substrate of FIG. 2 after UV-Ozone treatment and secondary mask deposition as viewed from the side at 50,000× magnification. The scale bar represents 0.5 μm.

FIG. 3A is a partial elevational view similar to FIG. 3 showing the example substrate of FIG. 1A following etching as taken along the line 3A-3A of FIG. 2A.

FIG. 4 is an SEM image of the substrate of FIG. 3 after removal of the silica spheres as viewed from above at 20,000× magnification. The scale bar represents 1 μm.

FIG. 5 is an SEM image of the substrate of FIG. 4 after surface texturing showing an inverted pyramid structure as viewed from above at 20,000× magnification. The scale bar represents 1 μm.

FIG. 6 is an SEM image of the substrate of FIG. 5 as viewed from the side. The scale bar represents 1 μm.

FIG. 6A is a partial elevational view similar to FIG. 3A showing surface texturing of the surface of the example substrate similar to FIG. 6 where the texturing includes a triangular pattern.

FIG. 7 is a photograph showing a perspective view of an example substrate including an as-deposited self-assembled monolayer of 1.57 μm silica spheres on the surface of a silicon wafer.

FIG. 8 is an SEM image of the substrate of FIG. 7 as viewed from above at 350× magnification. The scale bar represents 50 μm.

FIG. 9 is an SEM image of the substrate of FIG. 8 as viewed from above at 10,000× magnification. The scale bar represents 2 μm.

FIG. 10 is an SEM image of an example substrate including an as-deposited self-assembled monolayer of 1.57 μm silica spheres on the surface of a silicon wafer as viewed from above at 20,000× magnification. The scale bar represents 1 μm.

FIG. 11 is an SEM image of the substrate of FIG. 10 after 13 minutes of pattern etching to reduce the size of the silica spheres. The scale bar represents 1 μm.

FIG. 12 is an SEM image of the substrate of FIG. 10 after 16 minutes of pattern etching to reduce the size of the silica spheres. The scale bar represents 1 μm.

FIG. 13 is an SEM image of the substrate of FIG. 10 after 19 minutes of pattern etching to reduce the size of the silica spheres. The scale bar represents 1 μm.

FIG. 14 is an SEM image showing the results of buffered oxide etching for removal of silica spheres from a substrate with UV-ozone treatment as viewed from above at 10,000× magnification. The scale bar represents 2 μm.

FIG. 15 is an SEM image showing the results of buffered oxide etching for removal of silica spheres from a substrate without UV-ozone treatment as viewed from above at 10,000× magnification. The scale bar represents 2 μm.

FIG. 16 is an SEM image of an example substrate showing the results of 12 minutes of reactive ion etching following mask deposition and silica sphere removal as viewed from above at 20,000× magnification. The diameter of the pattern features after 12 minutes was about 1100 nanometers (nm). The scale bar represents 1 μm.

FIG. 17 is an SEM image of the substrate of FIG. 16 after 15 total minutes of reactive ion etching. The diameter of the pattern features after 15 minutes was about 950 nm. The scale bar represents 1 μm.

FIG. 18 is an SEM image of the substrate of FIG. 17 after 18 total minutes of reactive ion etching. The diameter of the pattern features after 18 minutes was about 800 nm. The scale bar represents 1 μm.

FIG. 19 is a plot showing the change in pattern diameter as a function of the amount of time the substrate was subjected to reactive ion etching. The diameter of the pattern features was observed to be inversely proportional to etching time with the diameter decreasing linearly at a rate of about 50 nm per minute.

FIG. 20 is an SEM image of a substrate as viewed from above at 20,000× magnification. Secondary mask deposition was performed without pattern etching and the primary mask material (silica spheres) was removed revealing a hexagonal pattern. The scale bar represents 1 μm.

FIG. 21 is an SEM image of the substrate of FIG. 16 showing an inverted pyramid structure resulting from wet etching with 1% KOH for 2 minutes as viewed from above at 10,000× magnification. The scale bar represents 2 μm.

FIG. 22 is an SEM image showing an enlarged view of the substrate of FIG. 21 at 20,000× magnification. The scale bar represents 1 μm.

FIG. 23 is an SEM image of the substrate of FIG. 22 as viewed from the side. The scale bar represents 1 μm.

FIG. 24 is an SEM image showing the results of buffered oxide etching for removal of silica spheres from a substrate without UV-ozone treatment as viewed from above at 50,000× magnification. The scale bar represents 500 nm.

FIG. 25 is an SEM image showing the results of buffered oxide etching for removal of silica spheres from a substrate with UV-ozone treatment as viewed from above at 50,000× magnification. The scale bar represents 500 nm.

FIG. 26 is an SEM image of the substrate of FIG. 24 showing non-uniform surface texturing as viewed from above at 20,000× magnification. The scale bar represents 1 μm.

FIG. 27 is an SEM image of the substrate of FIG. 25 showing uniform surface texturing as viewed from above at 20,000× magnification. The scale bar represents 1 μm.

FIG. 28 shows an example method for lithographic surface texturing according to the present disclosure.

Like reference numerals will be used to refer to like parts from figure to figure in the following detailed description.

### DETAILED DESCRIPTION OF THE INVENTION

As also discussed above, in various situations it may be useful to provide micro- and nano-scale surface texturing to alter the way a surface interacts with a light source. For example, it may be useful to provide surface texturing to improve the ability of a surface to absorb incident light as in the case of a photovoltaic cell for solar energy applications. However, current techniques for lithographic surface texturing may not be suited to processing large surface areas in an efficient and economic manner. While some patterning techniques (e.g., self assembly of colloidal particles) have been developed to provide lithography masks for large surface areas, optimization of the patterning process may be required for each new size, shape and type of patterning material. Moreover, it may not be possible to vary to dimensions of the lithograph mask after it has been patterned onto the target surface. Various other problems may also arise.

Use of the disclosed system and method for lithographic surface texturing may address these and other issues. For example, a primary mask material such as a self assembled monolayer of colloidal particles may be patterned onto the surface of a substrate with various techniques including spin-coating, dip coating and the like. The patterning process may be optimized for a single type of particles. After patterning, a pattern etching step may be used to controllably alter the dimensions and interparticle spacing of the primary mask material. This pattern etching step may be used to vary the surface texturing on the final product without varying the initial steps of the method. Subsequent to pattern etching, additional lithography steps may also be carried out.

In one aspect, a cost-effective, size-controllable surface lithography technique has been developed for providing micro- and nano-scale surface texturing with patterned colloidal particles. The disclosure may provide control over the dimensions and spacing of lithography mask features after deposition of the mask on a target surface. According to one aspect of the disclosure, silica spheres on the microand nano-scale may be patterned onto a target surface using various techniques such as spin-coating, dip-coating, and the like. The dimensions of the patterned surface may then be modified with a comparatively low-cost process such as reactive ion etching, potassium hydroxide (KOH) etching, and the like. The modified pattern may then be used to create micro- and nano-scale surface structures on a target surface. In general, the disclosure may be applicable to the fabrication of photovoltaics, microelectronics and other materials where effective light management may be a factor.

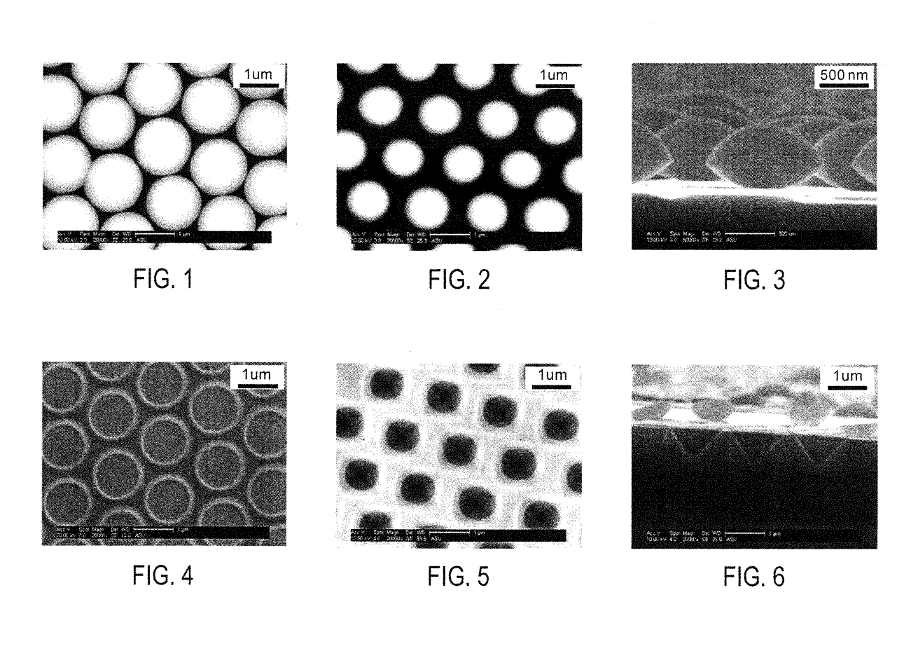

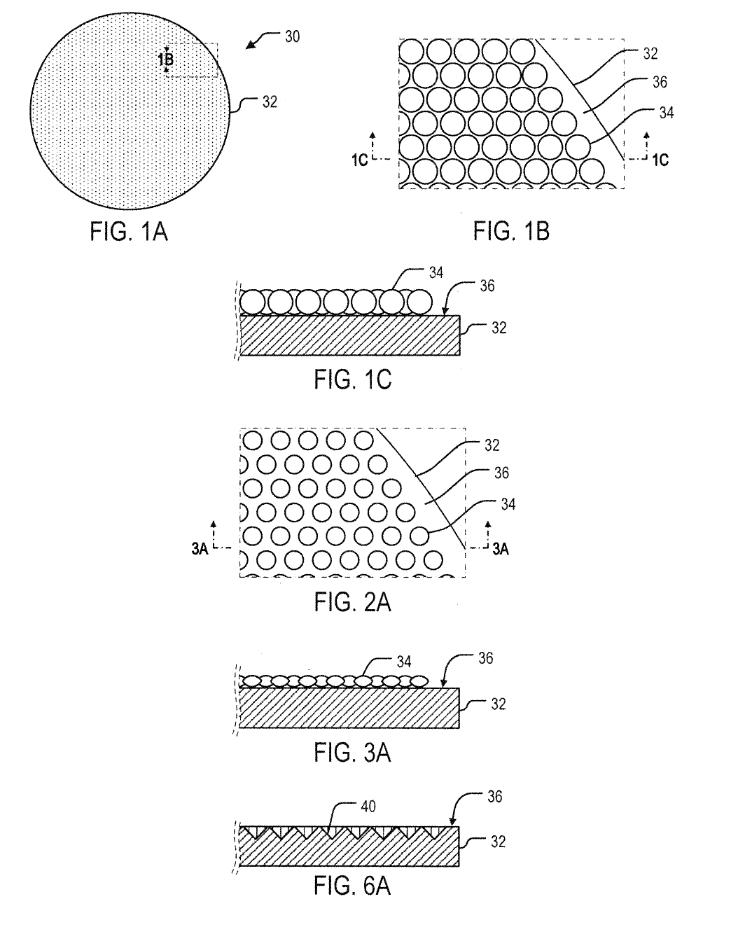

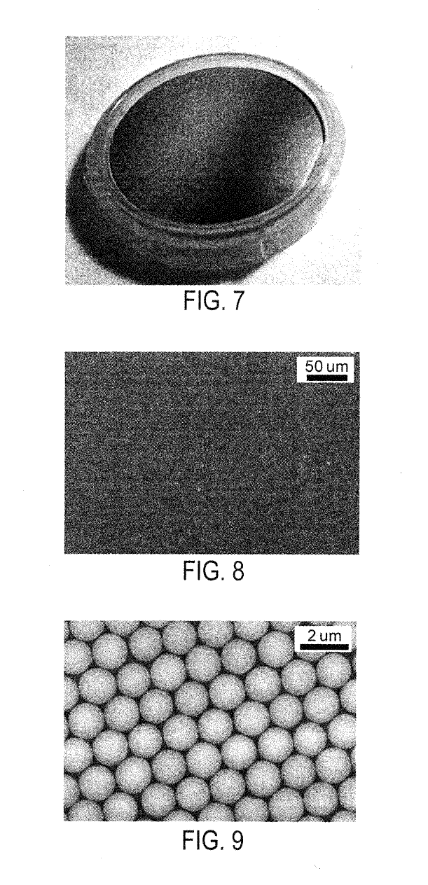

Turning now to the Figures, according to one embodiment, a method may include the step of preparing a sample by applying a primary mask material to a substrate. One example of a sample 30 is shown in FIGS. 1A-1C. The sample 30 includes a substrate 32 and a mask material comprised of a plurality of particles 34 deposited or patterned onto a target surface 36 of the substrate 32 as shown in FIGS. 1B and 1C (see also FIG. 1). In one aspect, the substrate 32 may be a silicon wafer as shown, for example, in FIG. 7. The plurality of particles 34 may be generally mono-disperse with each of the particles 34 having a substantially identical shape and size. For example, the particles 34 may be nano- or micro-scale silica spheres. Alternatively, the particles 34 may be poly-disperse with a range or shapes and sizes. The particles 34 may self-assemble on the target surface 36 to form an ordered monolayer with a regular pattern, such as a hexagonal close-packed structure. One method for patterning particles onto a surface is described in U.S. Provisional Patent Application No. 61/860,507 to Choi et al. filed on Jul. 31, 2013. However, any method for patterning particles onto a surface may be used in combination with the system and method of the present disclosure. Similarly, other primary mask materials may be used instead of, or in addition to the plurality of particles 34. For example, a photomask or photoresist may be used. In one aspect, the mask material is able to be etched, such as with reactive ion etching (RIE) to alter, ablate, or otherwise manipulate the dimensions of the primary mask material.

In some embodiments of a method, the patterned target surface 36 may be subjected to a pattern etching process such as reactive-ion etching in order to alter the dimensions of the material (e.g., the particles 34) that makes up the pattern as shown in FIGS. 2 and 2A. In one aspect, a pattern including particles 34 that are hexagonal close-packed silica spheres (see, for example, FIGS. 1 and 1B), can be subjected to a CHF₃/Ar RIE process to reduce the dimensions of each of the particles 34. The etching process may be configured to selectively etch only the pattern or mask material as opposed to the target surface 36 or the substrate 32, in general. In one aspect, the pattern etching process may be selected to etch the pattern or mask material (e.g., the particles 34) at a faster rate as compared with the target surface 36 or substrate 32. In another aspect, the pattern etching process may etch the particles 34 and the target surface 36 at the same rate or etch the target surface 36 at a faster rate than the particles 34.

With respect to the overall target surface 36, the majority of the particles 34 or other pattern material may be uniformly etched across the entirety of the target surface 36. For example, in the case of a monolayer of mono-disperse silica spheres, each of the spheres may be etched to uniformly reduce the diameter of the spheres. In another aspect, the pattern etching process may be isotropic or anisotropic. In the example case in which silica spheres are used, the diameter of the spheres may be uniformly etched in an isotropic process to maintain the spherical shape of the particles 34. However, in the case of anisotropic etching, the particles 34 may be etched in a directional fashion. For example, the particles 34 may be etched to reduce the overall height without significantly reducing the particles 34 in a width dimension (see, for example, FIGS. 3 and 3A). Pattern etching may also be applied selectively to regions of the target surface 36 such that one geographic region is etched more than another geographic region of the target surface 36.

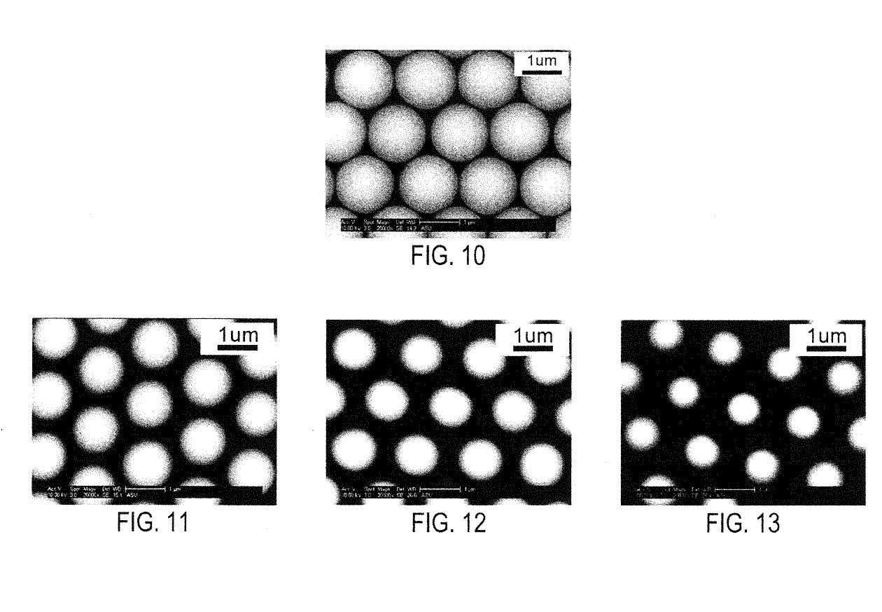

In one aspect, the amount of time that the pattern or mask material is subjected to the pattern etching process may have an effect on the extent of dimensional reduction achieved. FIGS. 10-13 show the results of a patterned sample after increasing pattern etching exposure times. In particular, FIG. 10 shows a target surface patterned with 1.57 μm silica spheres in a hexagonal close packed arrangement prior to pattern etching. RIE pattern etching was performed on the sample of FIG. 10 at 200 watts, 75 mTorr vacuum, and 25 sccm each of CHF₃ and Ar gases. FIGS. 11, 12 and 13 show the results of pattern etching after 13, 16 and 19 minutes respectively. Qualitatively, the size of the silica spheres is observed to decrease with increasing pattern etching time. Accordingly, the pattern etching time or rate may be varied to control the final dimensions of the particles in the case of silica spheres, or the dimensions of the pattern or mask material in general.

In some embodiments, as seen in FIGS. 10-13, the interparticle distance can be increased with pattern etching. Here, the interparticle distance may refer to the space between the exterior surfaces of adjacent particles as opposed to the distance between the centers of adjacent particles. For example, the distance between the centers of the particles, and in general, the geographic position of each of the particles does not change as a function of pattern etching time. However, the pattern etching process may reduce the diameter of each of the particles, thereby increasing the amount of space between the surfaces of adjacent particles. As described herein, control over the interparticle distance may contribute to the scale, dimensions and other parameters of a textured surface prepared according the system and method of the present disclosure.

In some embodiments, a method may include a decontamination step. In one aspect, the decontamination can occur following pattern etching. When preparing the pattern on the target surface, it is possible the other materials may be deposited on the target surface. For example, if a suspension of silica spheres in a liquid medium is applied to the target surface to prepare the pattern, then one or more components of the liquid medium may remain on the target surface. In another aspect, the pattern etching process may produce decomposition products or other debris that may remain on the target surface. The contaminants may include organic or inorganic materials that can have an effect on the efficiency and efficacy of the system and method of the disclosure. Therefore, one or more decontamination steps may before and after various steps in the method.

One decontamination technique includes ultraviolet ozone (UVO) treatment. UVO treatment may be used to decompose carbohydrates and other organic materials by ultraviolet irradiation to clean the target surface. For example, UVO can be used to decompose photoresist polymers. In one aspect, the UVO treatment process converts organic compounds into volatile substances such as water, carbon dioxide, nitrogen and the like. The decomposition process occurs as the result of incident ultraviolet energy in combination with an oxidizing atmosphere due to the presence of singlet oxygen species resulting from the formation and decomposition of O₃. When performed under vacuum or other suitable conditions, the volatile species may be removed from the contaminated surface.

In one example, a low-pressure mercury vapor lamp can produce UV light at wavelengths of 184.9 nm and 253.7 nm. Oxygen present in the system as O₂ can absorb energy at 184.9 nm to form ozone (O₃). In one aspect, O₂ may be split into two atomic oxygen species (O*). Each of the atomic oxygen species can form a bond with an O₂ molecule to form O₃. In another aspect, O₃ can absorb UV energy at 253.7 nm and decompose to yield atomic oxygen and O₂. The atomic oxygen species may have a strong oxidizing capability with respect to any organic contaminants which may be present. In one aspect, organic compounds irradiated with UV energy may form excited molecules or the free radicals that may react with atomic oxygen to form molecules such as CO₂, H₂O, N₂, and O₂, which may be removed from the target surface.

In one embodiment, the UVO treatment may be applied following the pattern etching step in order to remove contamination such as polymers which may impede subsequent steps in the method. For example, as will be described in greater detail herein, it may be useful to remove the etched pattern (e.g., etched silica spheres) from the target surface prior to further processing of the sample. Contaminants may inhibit the effective removal of silica sphere or another pattern material. Moreover, if not treated, contaminants present on the target surface may result is non-uniform etching during subsequent etching steps. In one aspect, a UVO treatment may be applied to remove other contaminants besides organic polymers. Similarly, other treatments may be applied to remove contaminants from the sample at various steps throughout a method of the present disclosure.

Yet another step in embodiments of a method can include deposition of a secondary mask material in addition to the patterned particles or other mask material applied previously. In one aspect, the application of the secondary mask material can occur subsequent to pattern deposition and pattern etching steps. Any secondary mask material may be applied to the patterned, etched sample. One example mask material may include a metal mask. The metal mask can include a single element such as chromium, nickel, cadmium or copper, or the metal mask may include a combination of metals such as chromium and nickel. The metal mask may be deposited on the sample using any suitable deposition technique such as thermal spray coating or vapor deposition.

In one example, a silica sphere pattern may be assembled on a target surface as in FIGS. 1 and 1B and the sample may be subjected to a pattern etching process to reduce the dimensions of the pattern as in FIGS. 2 and 2A. Following the pattern etching step, a metal mask including chromium and nickel may be deposited onto the patterned, etched target surface. In one aspect, deposition of a metal mask can provide a patterning effect on the target surface as the silica spheres or other pattern material block may mask certain portions of the target surface, thereby preventing metal mask deposition beneath those features. In some embodiments, a secondary mask may be applied to a larger portion of the target surface by increasing the extent of pattern etching, which in turn may result in a pattern material with smaller dimensions and reduced coverage of the target surface. Conversely, a greater portion of the target surface can be exposed (i.e., not covered by a secondary mask material) following deposition of the secondary mask by reducing the extent of pattern etching or by providing a pattern material with greater overall surface coverage.

In embodiments of a method in which a pattern material is applied to the surface, it may be useful to remove the pattern material at a later step in the method. For example, in the case of silica spheres patterned on a target surface, it may be useful to remove the silica spheres subsequent to pattern etching or secondary mask deposition. In order to remove to the primary pattern material, one or more selective etching or cleaning techniques may be relied upon. For example, it may be possible to remove silica spheres with a buffered oxide etch (BOE) solution such as a mixture of ammonium fluoride and hydrofluoric acid. In one aspect, a BOE solution can include hydrochloric acid to dissolve insoluble products produced in the presence of hydrofluoric acid, thereby improving the overall primary pattern material removal process. Another BOE solution can include a 6:1 volume ratio of 40% NH₄F in water to 49% HF in water. However, other volume ratios such as a 10:1 ratio may be used. Other techniques to remove a primary pattern material such as silica spheres subjected to pattern etching and secondary mask deposition may also be used.

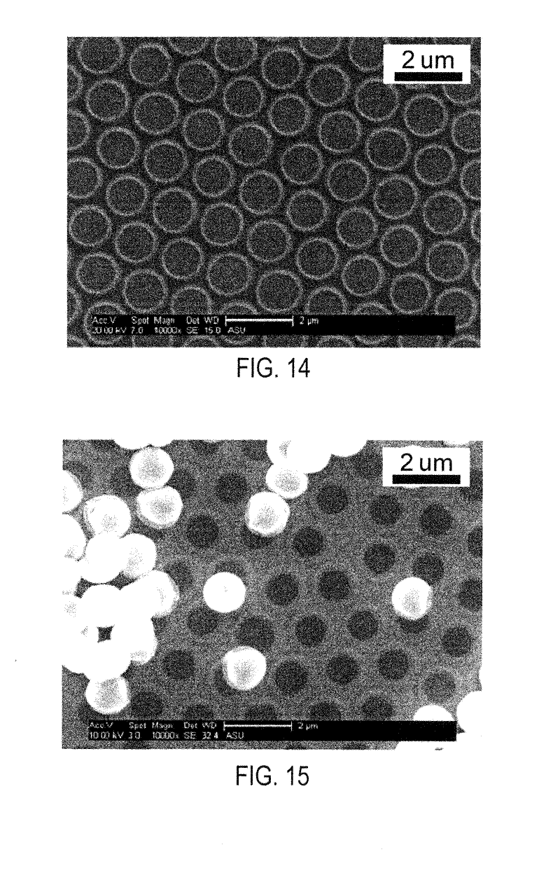

FIGS. 14 and 15 show samples where a primary pattern material was removed with a BOE solution with (FIG. 14) or without (FIG. 15) a UVO treatment. For each sample, the target surface was patterned with 1.57 μm silica spheres and the samples were subjected to a pattern etch to reduce the size of the silica spheres. Next, a metal mask including chromium and nickel was deposited on the surface of the samples. Prior to the metal mask deposition step, the sample shown in FIG. 14 was subjected to a UVO treatment for 30 minutes whereas the sample shown in FIG. 15 was left untreated. Following metal mask deposition, each of the samples was dipped in a BOE solution for 20 minutes to remove the silica spheres. While no silica spheres were observed to remain in FIG. 14, several silica spheres remained on the surface in FIG. 15. Therefore, FIGS. 14 and 15 show that it may be useful to perform a UVO or other similar treatment in order to effectively remove the primary mask material at a subsequent point in the method.

FIGS. 14 and 15 also show that the target surface is patterned with circular areas absent of any secondary mask material (i.e., chromium/nickel metal) where the silica spheres resided prior to treatment with the BOE solution. Accordingly, a primary mask material such as silica spheres may be able to prevent the deposition of a secondary mask material on portions of the target surface covered by the primary mask material. Similarly, by performing a pattern etch step, the surface area covered by the primary mask material may be reduced to enable deposition of the secondary mask material on the target surface in the uncovered areas.

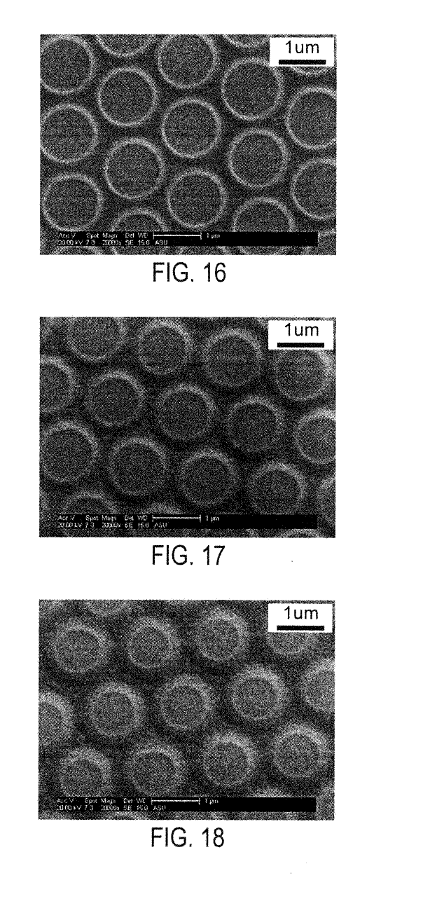

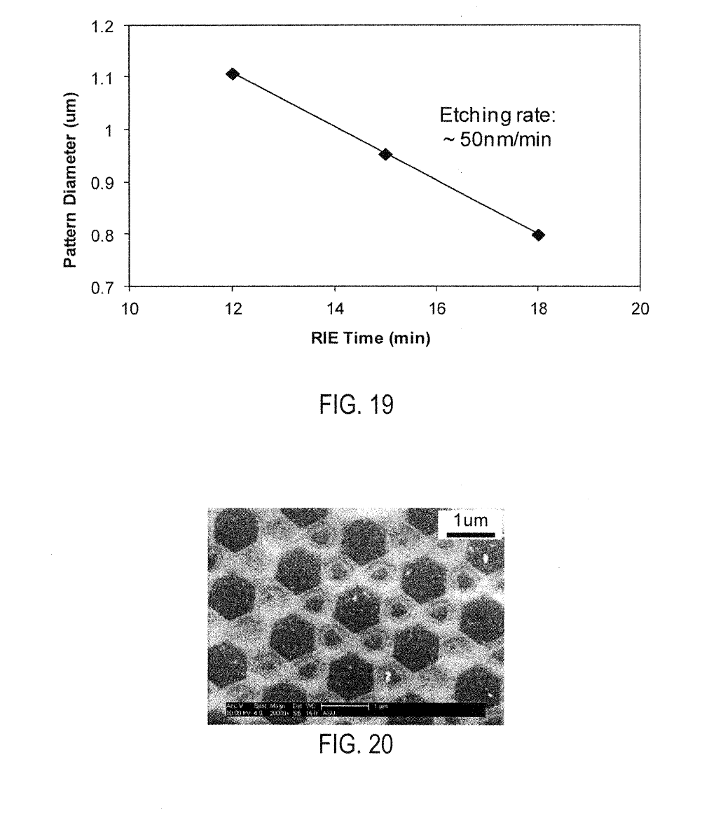

FIGS. 16-18 show a number of examples prepared similarly to samples shown in FIG. 14. However, each of the samples was subjected to varying degrees of pattern etching as discussed with reference to FIGS. 11-13. In particular, the samples in FIGS. 16, 17 and 18 were subjected to a pattern etching step for 12, 15 and 18 minutes respectively. Following UVO treatment, secondary metal mask deposition and BOE treatment to remove the silica spheres, the circular features present on the target surface of the samples were measured. The circular features in FIG. 16 had an average diameter of about 1100 nm, the features in FIG. 17 had an average diameter of about 950 nm, and the average diameter of the features in FIG. 18 was about 800 nm. These data were plotted as shown in FIG. 19. The feature diameter was found to be inversely proportional to the time a sample was subjected to pattern etching. The slope of the linear relationship was 50 nm min⁻¹, which corresponds to the pattern etching rate.

FIG. 20 also shows an example of target surface prepared with silica spheres where the pattern etching step was omitted. After performing a secondary mask deposition step including a chromium/nickel metal mask, a unique hexagonal pattern was observed after removal of the silica spheres. Accordingly, it may be useful to forego a pattern etching step altogether in certain embodiments of the system and method of the present disclosure.

In another step of method according to the disclosure, the sample may be subjected to a surface texturing process. In some embodiments, the surface texturing step may be carried out subsequent to removal of the primary mask material. For example, surface texturing may be applied to the samples as shown in FIGS. 16-18 where a portion of the target surface is protected with a secondary mask material and another portion of the target surface is unprotected following removal of the primary mask material. The surface texturing step can include an etching process such as a wet or dry etching process. In one aspect, the type of etching process selected may determine the characteristics of the structure (e.g., rod, tip, inverted pyramid) that results from the surface texturing step.

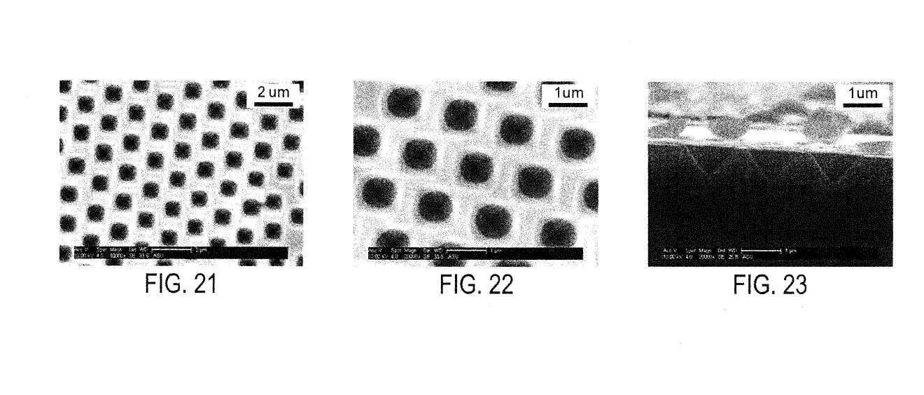

With reference to one surface texturing example shown in FIGS. 21-23, a wet etching step was used to provide an array of inverted square pyramid structures on a target surface. In particular, a sample prepared as shown in FIG. 16 was subjected to a wet etching process including dipping the sample in a 1% dilute KOH solution at 87° C. for 2 minutes. As shown in FIGS. 21-23, the target surface is preferentially etched at the unprotected areas where the secondary mask material was not deposited due to the presence of the primary mask material. The resulting inverted square pyramid structures extend into the target surface. The triangular cross-section of the surface texturing is shown in FIG. 23. Another example of a target surface 36 having surface texturing including a triangular pattern 40 is shown in FIG. 6A.

Whereas one example of surface texturing is shown in FIGS. 21-23, other sizes, geometries, orientations and spatial arrangements/patterns of surface texturing may be achieved with the system and method of the present disclosure. Variables that may have an effect on the surface texturing achieved can include the shape and size of the particles used to provide the primary mask pattern, the extent and type of pattern etching (e.g., wet, dry, isotropic, anisotropic), the efficacy of any primary mask removal step, the type of secondary mask and the method of deposition, the extent and type of surface texturing, and the use of a decontamination treatment step (e.g., UVO).

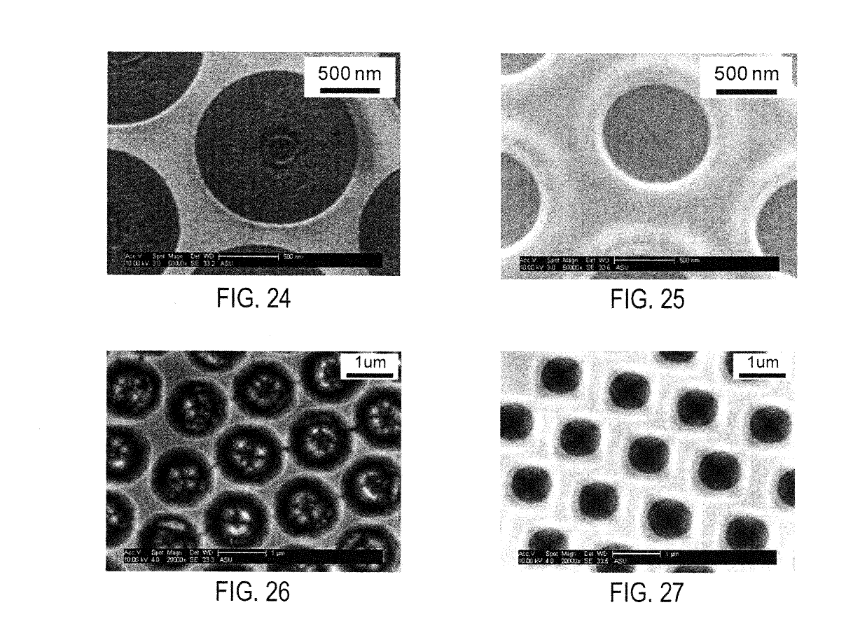

For example, FIGS. 24-27 illustrate the effects of a UVO treatment on surface texturing. FIG. 24 shows a sample that did not receive a UVO treatment analogous to FIG. 14. As a result, the unprotected areas in FIG. 24 are contaminated with an organic material. Meanwhile, FIG. 25 shows a sample that did receive a UVO treatment analogous to FIG. 15. Accordingly, no organic contaminants may be seen in the unprotected areas in FIG. 25. After performing a wet etching surface texturing step on each of the samples in FIGS. 24 and 25, the resulting sample were observed to have different characteristics. Wet etching of the sample in FIG. 24 resulted in non-uniform etching as shown in FIG. 26, whereas wet etching of the sample in FIG. 25 resulted in generally uniform etching as shown in FIG. 27. In one aspect, it may be useful to produce either uniform or non-uniform etching depending on what characteristics are to be imparted to the target surface. Further methods for producing surface texturing are described in U.S. Patent Application Publication No. 2014/0342492, which is herein incorporated by reference in its entirety. However, any method for surface texturing may be used in combination with the system and method of the present disclosure.

In some embodiments of a method, it may be useful to remove a secondary mask material from the target surface. In one aspect, the secondary mask may be removed using a variety of etching techniques that may be selective for removal of the secondary mask material. For a chromium metal mask, one possible wet etching method may include a 1:1 solution of glycerol and dilute hydrochloric acid (e.g., 10% HCl in water). However, other etching techniques including dry etching technique such as plasma etching may also be used. In one example method, the secondary mask removal step may occur subsequent to a surface texturing step.

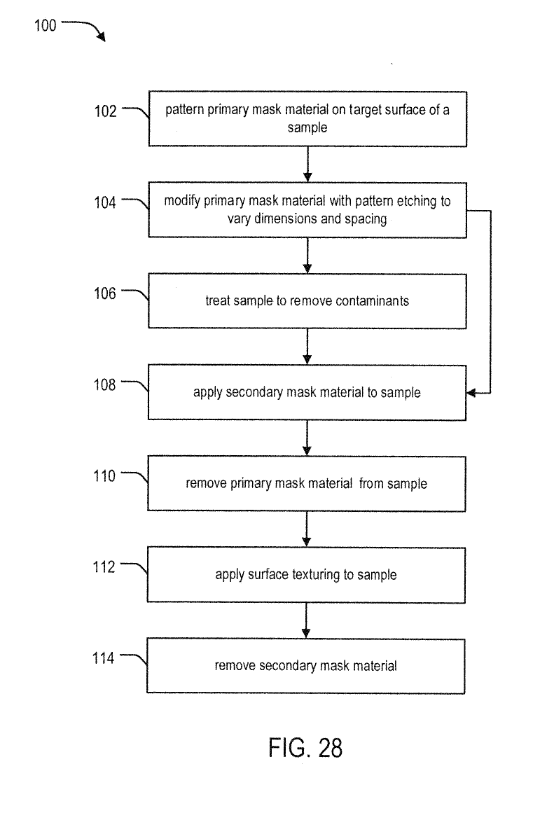

Turning now to FIG. 28, an example method 100 for texturing a target surface is shown. In a first step 102 of the method 100, a sample is prepared by providing a primary mask on a target surface. In one example shown in FIG. 1, the primary mask can include a self assembled monolayer of monodisperse micro-scale silica spheres. However, as described elsewhere, other types of particles such as colloidal particles or other types of primary masks may be used alternatively, or in addition to silica spheres. Similarly, the dimensions (e.g., micro- vs. nano-scale) of the particles or non-particle based primary mask material may be varied.

In a next step 104 of the method 100, the patterned primary mask material may be exposed to an etching process in order to alter the dimensions (e.g., size, spacing) of the primary mask. In the example case of patterned silica spheres as shown in FIGS. 1 and 1B, the diameter and interparticle spacing may be simultaneously varied with an RIE process to provide a sample as shown, for example, in FIGS. 2 and 2A. Accordingly, this step may provide for a set of methods that begin with the same size silica spheres that may be controllably scaled to varying extents to provide a continuous spectrum of primary mask dimensions. In one aspect, the use of a single size and shape of particles as a starting point for a method, such as example method 100, may reduce the amount of time spent on optimizing a primary mask material patterning step. By contrast, in the case where particles sizes are varied to affect the resulting surface texturing, a significant amount of time may be spent on optimizing each different particle size. It will be appreciated that step 104 may be omitted where the primary mask material is patterned at the target dimension.

In a subsequent step 106, the patterned sample may be treated to remove contaminants such or organic and inorganic materials. In one embodiment, a UVO treatment is applied to the sample to oxidize organic materials into compounds that may be more volatile and removable from the sample under vacuum, for example. A UVO treatment may be included in the method 100 if it is useful to remove a majority of the primary mask material. In another aspect, a UVO treatment may be useful to achieve more uniform surface texturing during a subsequent step of the method 100. Alternatively, the UVO treatment may be omitted or only partially completed. For example, is may be useful to leave a portion of the primary mask material on the target surface. Moreover, it may be useful to achieve non-uniform etching of the target surface. Therefore in some embodiments of a method 100, step 106 may be bypassed as illustrated in FIG. 28.

Continuing with a step 108 of the method 100, a secondary mask material may be deposited on the patterned sample. An example of a sample processed through step 108 of the method 100 is shown in FIG. 3. As described above, the secondary mask may be applied with or without a prior (or subsequent) decontamination step. In one aspect, a secondary mask can be applied to protect the areas on the target surface that are not covered by the primary pattern. In a subsequent step 110, the primary surface may then be removed, revealing portions of the target surface that are not protected by the secondary mask material. An example of a sample processed through step 110 of the method 100 is shown in FIG. 4, where the generally round silica spheres were removed after deposition of a chromium-nickel mask to reveal an array of unprotected circular features on the target surface.

In a next step 112 of the method 100, the sample may be subjected to surface texturing. In one aspect, the unprotected portions of the target surface (i.e., the areas not covered with the secondary mask material) may be selectively etched. FIGS. 5 and 6 show one example of a sample that was processed through step 112 including a UVO treatment step 106. The sample in FIGS. 5 and 6 include uniformly etched inverted square pyramids formed in the unprotected areas of the target surface. In another aspect, a step 112 may include one or more substeps in which various etching techniques are performed in series or in parallel to achieve a particular result.

Following step 112, a further step 114 of the method 100 may be carried out to remove the secondary mask material. Removal of the secondary mask material may be useful, for example, to further process the sample through one or more additional process steps (not shown). In general, it will be appreciated that the method 100 is presented by way of illustration and is not meant to be limiting. Therefore, the method 100 may be carried out in any order with steps repeated, added or omitted to achieve a particular outcome.

In one aspect, the system and methods of the present disclosure may be applied for the fabrication of nano- and micro-scale structures for a diversity of applications including, but not limited to solar cell fabrication and the development of thin-wafer solar cells. In another aspect, the disclosure may provide a cost-effective lithography technique which may also offer control over the size of the primary pattern in to fabricate scale-controllable surface structures. Moreover, reductions in process time and cost may also be realized on the industrial scale. In yet another aspect, the disclosure may provide control over light management (e.g., absorption and reflection characteristics) over relatively large surface areas.

Whereas current nano-/micro-lithography techniques using silica spheres may vary the size of the particles to fabricate a particular surface structure, the present disclosure provides for at least one approach to vary the dimensions of the pattern after it has been formed on the target surface. With respect to the conventional approach, the primary mask material or pattern may only be changed by using differently dimensioned starting materials. Accordingly, there may be little control over interparticle spacing (a parameter that may be considered for optimizing light management). Moreover, un-expected patterning may occur with as the dimensions of the primary mask material are scaled. In another aspect, re-optimization of the patterning process may be needed when changing the dimensions of the primary mask material as well as the target surface.

By contrast, the present disclosure may afford control over the size and spacing of a primary mask pattern with a cost effective etching process. In addition, an ultraviolet ozone treatment process may be included to improve the removal of the primary mask material subsequent to a pattern etching step. Therefore, a target surface may be fabricated with various structures or other surface texturing features without changing the dimensions of the starting material used for the primary mask pattern.

### Example I

Silica sphere monolayer spin-coating was carried out to prepare silica nano-/micro-sphere patterned samples. A monolayer of silica spheres was deposited on the surface of a 2 inch silicon wafer. A solvent-controlled silica sphere spin-coating method was used as described in U.S. Provisional Application 61/860,507. In general, after cleaning in piranha solution (H₂SO₄:H₂O₂=4:1) a 2 inch silicon wafer was placed in a spin-coater and a 650 mg/ml suspension of silica spheres was applied to the surface. The wafer was then accelerated to 2000 rpm at 80 rpm/sec for a total duration of 120 seconds under ambient conditions. The 650 mg/ml suspension of silica spheres was prepared in N,N-dimethyl-formamide by sonication for a period of 5 hours.

Size reduction of silica spheres was achieved with a reactive ion etching process. After spin-coating silica spheres to form a monolayer on surface of the wafer, the size of the silica spheres was reduced to produce the desired pattern dimensions. Reactive ion etching (RIE) was used for silica sphere size reduction. A 1:1 ratio of CHF₃:Ar gas was supplied at 50 sccm, 200 watts power, and 75 mTorr pressure with etching time varied to achieve the desired dimensions of the primary pattern. Under the described conditions, a horizontal etching rate of about 50 nm/min was observed

Metal mask deposition was carried out subsequent to RIE. A metal masks was co-deposited including Cr (50 nm) and Ni (20 nm). Silica sphere removal was carried out with a 10:1 BOE for 20 minutes.

Where described, a UVO treatment was applied prior to silica sphere removal to remove organic compounds on the sample surface following the RIE pattern etching process. After CHF₃/Ar RIE process, Si-organic compounds formed which impeded the effective removal of the silica spheres from the sample surface. In general, UVO treatment was applied to sample for 30 minutes.

Etching the patterned surface was carried out with a KOH wet-etching technique. The patterned sample was dipped in a 1% dilute KOH solution at 87° C. for 2 minutes resulting in an inverted square pyramid structure.

The schematic flow chart shown in FIG. 28 is generally set forth as a logical flow chart diagram. As such, the depicted order and labeled steps are indicative of one embodiment of the presented method. Other steps and methods may be conceived that are equivalent in function, logic, or effect to one or more steps, or portions thereof, of the illustrated method. Additionally, the format and symbols employed in FIG. 28 are provided to explain the logical steps of the method and are understood not to limit the scope of the method. Although various arrow types and line types may be employed, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

The present invention has been described in terms of one or more preferred embodiments, and it should be appreciated that many equivalents, alternatives, variations, and modifications, aside from those expressly stated, are possible and within the scope of the invention.

Each reference identified in the present application is herein incorporated by reference in its entirety.

What is claimed is:

1. A method of manufacturing an etched surface, the method comprising:
(a) assembling a primary mask material including a plurality of particles on the surface of a substrate;
(b) etching the first mask material;
(c) depositing a secondary mask material on the substrate including the etched primary mask material;
(d) removing at least a portion of the etched primary mask material from the substrate, thereby exposing the substrate beneath the primary mask material; and
(e) etching the substrate exposed in step (d).

2. The method of claim 1, further including treating the primary mask material prior to step (c) to remove organic contaminants.

3. The method of claim 2, wherein treating the primary mask material to remove organic contaminants includes an ultraviolet-ozone treatment.

4. The method of claim 1, wherein the plurality of particles includes silica spheres.

5. The method of claim 1, wherein the plurality of particles has an average diameter of about 10 nanometers to about 10 micrometers.

6. The method of claim 1, wherein step (a) further includes forming a self-assembled monolayer.

7. The method of claim 1, wherein step (b) further includes reactive ion etching.

8. The method of claim 1, wherein step (b) further includes varying at least one of a size and an interparticle spacing of the plurality of particles.

9. The method of claim 1, wherein the mask material of step (c) includes a metal.

10. The method of claim 9, wherein the metal includes at least one of chromium and nickel.

11. The method of claim 1, wherein step (d) further includes at least one of hydrofluoric acid etching and buffered oxide etching.

12. The method of claim 1, wherein step (e) further includes at least one of reactive ion etching and wet etching.

13. A method of manufacturing an etched surface, the method comprising:
(a) spin-coating a primary mask material onto a target surface of a substrate, the primary mask material comprising a plurality of spherical particles, the particles self-assembling into an ordered monolayer on the target surface;
(b) etching the particles using a reactive ion composition;
(c) decontaminating the particles and the target surface with an ultraviolet ozone treatment;
(d) depositing a secondary mask material on the particles and a portion of the target surface not masked by the particles;
(e) removing at least a portion of the particles from the substrate, thereby exposing a remaining portion of the target surface previously masked by the particles; and
(f) etching the substrate exposed in step (e).

14. The method of claim 13, wherein the particles are silica spheres.

15. The method of claim 14, wherein the silica spheres have an average diameter of about 10 nanometers to about 10 micrometers.

16. The method of claim 14, wherein the silica spheres have an average diameter of about 100 nanometers to about 5 micrometers.

17. The method of claim 14, wherein the silica spheres have an average diameter of about 500 nanometers to about 1500 nanometers.

18. The method of claim 13, wherein step (b) further includes varying at least one of a size and an interparticle spacing of the particles.

19. The method of claim 13, wherein the secondary mask material includes a metal.

20. The method of claim 19, wherein the metal includes at least one of chromium and nickel.

21. The method of claim 13, wherein step (e) further includes at least one of hydrofluoric acid etching and buffered oxide etching.

22. The method of claim 13, wherein step (f) further includes at least one of reactive ion etching and wet etching.

23. The method of claim 13, wherein the particles self assemble into a hexagonal close packed arrangement.

24. The method of claim 13, wherein step (b) further includes increasing an interparticle distance between the particles.

25. The method of claim 13, wherein step (b) further includes one of anisotropic etching and isotropic etching.
